(19) United States
(12) Patent Application Publication
(10) Pub. No.: US 2025/0046669 A1
(43) Pub. Date: Feb. 6, 2025

(54) ELECTRONIC COMPONENT WITH HEAT DISSIPATING PART

(71) Applicant: DENSO CORPORATION, Kariya-city (JP)

(72) Inventors: Takuya Mitsuhashi, Kariya-city (JP); Kimio Kohara, Kariya-city (JP); Yoichiro Kawamoto, Kariya-city (JP)

(21) Appl. No.: 18/921,484

(22) Filed: Oct. 21, 2024

Related U.S. Application Data
(63) Continuation of application No. PCT/JP2023/016796, filed on Apr. 28, 2023.

(30) Foreign Application Priority Data
May 13, 2022 (JP) 2022-079355

(51) Int. Cl. H01L 23/367; H01L 23/373

(52) U.S. Cl. CPC H01L 23/3672; H01L 23/3736

(57) ABSTRACT

An electronic component with heat dissipating part includes: an electronic part, a heat radiating part, and a joining member. The electronic part generates heat during operation. The heat radiating part radiates heat generated by the electronic part to an ambient fluid. The joining member joins the electronic part and the heat radiating part. A joint area between the electronic part and the heat radiating part is 100 mm² or more. The joining member forms a porous metal layer in which pores are uniformly distributed throughout.

### CROSS REFERENCE TO RELATED APPLICATION

The present application is a continuation application of International Patent Application No. PCT/JP2023/016796 filed on Apr. 28, 2023, which designated the U.S. and claims the benefit of priority from Japanese Patent Application No. 2022-79355 filed on May 13, 2022. The entire disclosures of all of the above applications are incorporated herein by reference.

### TECHNICAL FIELD

The present disclosure relates to an electronic component with heat dissipating part and a method for manufacturing the same.

### BACKGROUND

In an electronic component with heat dissipating part, a heat radiating part is integrally formed with an electronic part to radiate heat from the electronic part.

### SUMMARY

According to an aspect of the present disclosure, an electronic component with heat dissipating part includes: an electronic part to generate heat during operation; a heat radiating part configured to radiate heat generated by the electronic part to an ambient fluid; and a joining member to join the electronic part and the heat radiating part. The joint area between the electronic part and the heat radiating part is 100 mm² or more, and the joining member forms a porous metal layer in which pores are uniformly distributed.

### BRIEF DESCRIPTION OF DRAWINGS

FIG. 1 is an explanatory diagram showing an overall configuration of a semiconductor device in an embodiment.

FIG. 2 is an explanatory diagram showing a surface of a joining member in the embodiment.

FIG. 3 is a characteristic diagram showing a relationship between an inter-pore distance and a durability index in a porous metal layer.

FIG. 4 is a characteristic diagram showing a relationship between a thickness dimension and a void ratio in a porous metal layer.

FIG. 5 is an explanatory diagram showing a bonding surface of a heat radiating part in the embodiment.

### DETAILED DESCRIPTION

An electronic component with heat dissipating part has been developed in which a heat radiating part is integrally formed with an electronic part to radiate heat from the electronic part. A technique may be provided to reduce the void ratio of the solder to 10% or less when the heat radiating part and the electronic part are joined by soldering in an electronic component with heat dissipating part. Thereby, the thermal resistance of the joint can be reduced, so that the heat dissipation performance can be improved.

However, in case where the void ratio of the solder is made small at the joint, when thermal stress is applied to the joint, it becomes difficult to absorb the stress. This may make it easier for the joint to have cracks.

The present disclosure provides an electronic component with heat dissipating part and a method for manufacturing the same, to achieve improvement in both of the heat dissipation performance and the durability.

According to an aspect of the present disclosure, an electronic component with heat dissipating part includes: an electronic part to generate heat during operation; a heat radiating part configured to radiate heat generated by the electronic part to an ambient fluid; and a joining member to join the electronic part and the heat radiating part. The joint area between the electronic part and the heat radiating part is 100 mm² or more, and the joining member forms a porous metal layer in which pores are uniformly distributed.

According to this, since the joining member forms the porous metal layer, the temperature distribution can be made small over the entire surface of the joining member. Further, even if a crack occurs in the joining member, it can be absorbed by the pores, so that cracks can be restricted from spreading. As a result, it is possible to achieve improvement both in heat dissipation and durability.

Further, a method for manufacturing an electronic component with heat dissipating part, according to one aspect of the present disclosure, which is formed by joining an electronic part to generate heat during operation with a heat radiating part configured to radiate heat generated by the electronic part to an ambient fluid. In the method, the joint area between the electronic part and the heat radiating part is 100 mm² or more. The method includes a printing step to apply paste solder, which is a joining member to join the electronic part and the heat radiating part, to at least one of a bonding surface of the electronic part and a bonding surface of the heat radiating part through a screen mesh.

According to this, the number of pores in the joining member can be increased, so that the temperature distribution can be reduced over the entire surface of the joining member. Further, even if a crack occurs in the joining member, it can be absorbed by the pores, so that cracks can be restricted from spreading. As a result, it is possible to achieve improvement both in heat dissipation performance and durability.

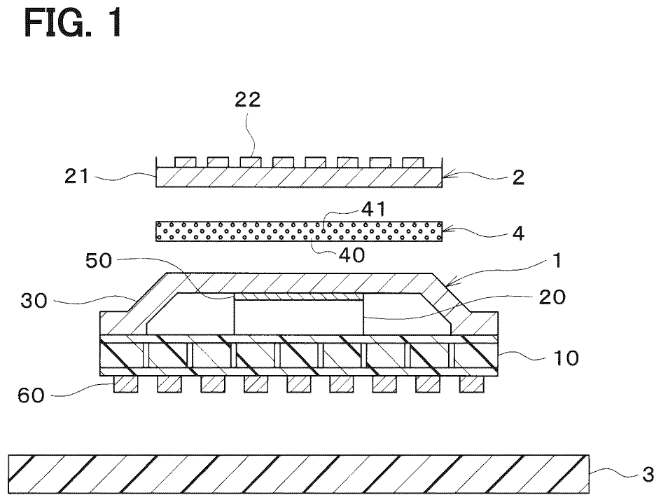

Hereinafter, an embodiment of the present disclosure will be described with reference to the drawings. As shown in FIG. 1, this embodiment employs a semiconductor device 1 integrally provided with a heat radiating part 2 as an electronic component with heat dissipating part. The semiconductor device 1 of this embodiment includes a substrate 10, a semiconductor element 20, and a lid 30. The semiconductor device 1 of this embodiment corresponds to an electronic part.

The substrate 10 functions as an interposer for the semiconductor element 20 when the semiconductor device 1 is mounted on a motherboard 3, which is an external member. The substrate 10 is mounted on the top surface of the motherboard 3 via a solder bump 60. More specifically, the substrate 10 is mounted on the upper surface of the motherboard 3 via the solder bump 60, with the lower surface of the substrate 10 facing the upper surface of the motherboard 3. As the substrate 10, for example, a ceramic substrate, a printed circuit board, a glass epoxy substrate, etc. can be used.

The semiconductor element 20 is mounted on the upper surface of the substrate 10 via a bump electrode (not shown). More specifically, the semiconductor element 20 is mounted on the upper surface of the substrate 10 via a bump electrode, with the front surface (that is, the lower surface) of the semiconductor element 20 facing the upper surface of the substrate 10.

The semiconductor element 20 is flip-chip bonded onto the upper surface of the substrate 10. The semiconductor element 20 can be an IC chip or the like formed by a general semiconductor process. Further, the bump electrode is provided on the surface of the semiconductor element 20 and is made of solder, gold, Cu, or the like.

The lid 30 is a sealing member that seals the semiconductor element 20. The lid 30 is fixed onto the upper surface of the substrate 10 via a sealant (not shown). Further, the back surface (that is, the upper surface) of the semiconductor element 20 and the lid 30 are bonded together by an adhesive 50. The sealing material and the adhesive 50 can be made of a material having a higher melting temperature than the bump electrode.

The heat radiating part 2 is a heat radiating member that radiates heat generated by the semiconductor device 1 to air, which is an ambient fluid. The heat radiating part 2 is made of a material with excellent thermal conductivity. In this embodiment, the heat radiating part 2 is made of metal such as aluminum or copper. The heat radiating part 2 has a plate portion 21 and a fin portion 22.

The plate portion 21 is formed into a plate shape. The plate portion 21 is arranged in contact with the upper surface of the lid 30 of the semiconductor device 1 (that is, opposite to the surface to which the semiconductor element 20 is bonded). The fin portion 22 is a heat transfer member that increases the heat transfer area with the air and promotes heat exchange between the air and the semiconductor device 1. The fin portion 22 is provided to protrude upward from the upper surface of the plate portion 21 (that is, opposite to the surface in contact with the lid 30).

The semiconductor device 1 and the heat radiating part 2 are joined by a joining member 4. In this embodiment, the joining member 4 is made of solder. That is, the semiconductor device 1 and the heat radiating part 2 are joined by solder. At least one of a bonding surface of the semiconductor device 1 with the joining member 4 and a bonding surface of the heat radiating part 2 with the joining member 4 is plated with nickel.

The joint area between the semiconductor device 1 and the heat radiating part 2 is 100 mm² or more. In this embodiment, the joint between the semiconductor device 1 and the heat radiating part 2 is 30 mm square, and the joint area between the semiconductor device 1 and the heat radiating part 2 is 900 mm².

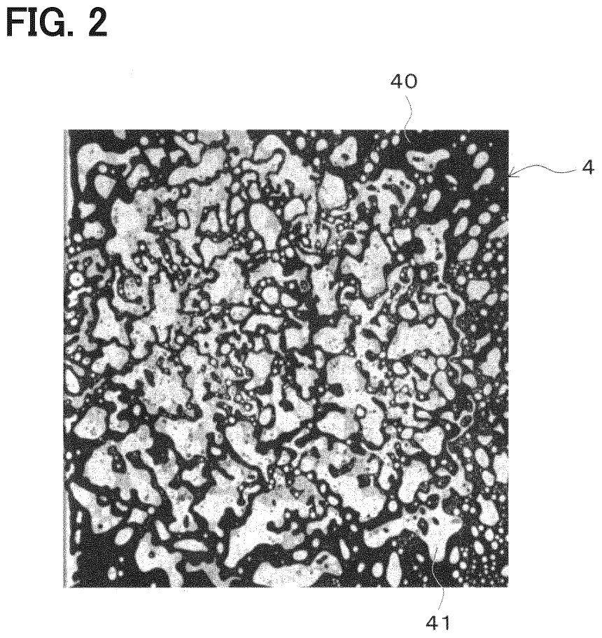

As shown in FIG. 2, the joining member 4 forms a porous metal layer 40 in which pores 41 are uniformly distributed throughout. FIG. 2 shows the surface of the joining member 4 of this embodiment seen from the upper side (namely, the surface adjacent to the heat radiating part 2).

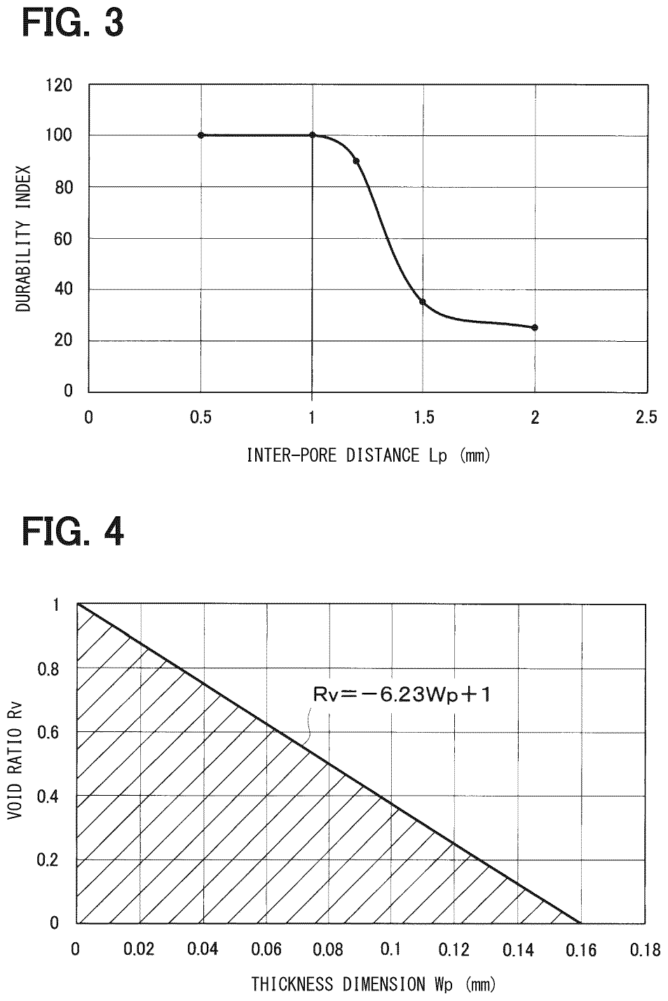

Here, the distance between adjacent pores 41 in the porous metal layer 40 is defined as an inter-pore distance Lp. FIG. 3 shows the relationship between the inter-pore distance Lp and the durability in the porous metal layer 40. The durability index on the vertical axis in FIG. 3 is an index indicating the high durability of the joining member 4 and the substrate 10 against damage due to long-term use. The larger the durability index value, the higher the durability. Note that “damage to the joining member 4 and the substrate 10 due to long-term use” here is caused by thermal strain, thermal deterioration, pressure fluctuation, swelling, and the like.

As is clear from FIG. 3, when the inter-pore distance Lp becomes larger than 1 mm, the durability rapidly decreases. Therefore, the porous metal layer 40 is formed such that the inter-pore distance Lp is smaller than 1 mm at any location. That is, the porous metal layer 40 is formed such that the inter-pore distance Lp is smaller than 1 mm at any location within the porous metal layer 40. In other words, the porous metal layer 40 has at least one pore 41 formed within a unit area of 1 mm² when viewed from a direction perpendicular to the bonding surface between the semiconductor device 1 and the heat radiating part 2. Thereby, the durability can be improved.

Here, the length of the porous metal layer 40 in the arrangement direction in which the semiconductor device 1 and the heat radiating part 2 are arranged is defined as a thickness dimension Wp. A ratio of an area of the pores 41 included per unit area (1 mm²) when the porous metal layer 40 is viewed in the direction perpendicular to the bonding surface is defined as a void ratio Rv. In this embodiment, the arrangement direction of the semiconductor device 1 and the heat radiating part 2 in the porous metal layer 40 is parallel to a direction perpendicular to the bonding surface of the porous metal layer 40.

According to studies by the present inventors, as shown in the shaded area in FIG. 4, in the semiconductor device 1 of this embodiment, it was found that heat dissipation performance can be improved when the thickness dimension Wp and the void ratio Rv of the porous metal layer 40 satisfy the relationship of Rv≤−6.23Wp+1. At this time, in the porous metal layer 40, the temperature difference dT is 1° C., the heat transfer coefficient \ is 64.2 W/(m·K), and the heat flow rate q is 400 kW/m². Therefore, in this embodiment, the thickness dimension Wp and the void ratio Rv of the porous metal layer 40 are set to satisfy the relationship Rv≤−6.23Wp+1.

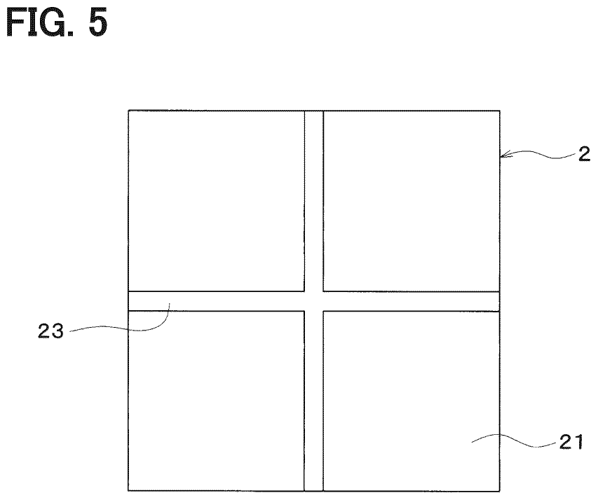

As shown in FIG. 5, a groove portion 23 is formed in the bonding surface of the plate portion 21 of the heat radiating part 2 with the joining member 4. The end of the groove portion 23 is open to the outside of the heat radiating part 2. That is, the inside of the groove portion 23 communicates with the outside of the heat radiating part 2 (that is, air is the ambient fluid). In this embodiment, two groove portions 23 are linearly formed to intersect with each other in a cross shape on the bonding surface of the plate portion 21 with the semiconductor device 1.

Next, a method for manufacturing the semiconductor device 1 in which the heat radiating part 2 of this embodiment is integrally provided will be described. First, a preparation step is performed to prepare the semiconductor device 1 and the heat radiating part 2.

Next, a printing step is performed. In the printing step, paste solder is applied to at least one of the bonding surface of the semiconductor device 1 and the bonding surface of the heat radiating part 2 through a screen mesh. The paste solder contains a flux material that improves solder bonding properties. In this embodiment, the content of flux material in the solder is approximately 50%.

Subsequently, a bonding step is performed in which the joint of the semiconductor device 1 and the heat radiating part 2 is soldered. In this embodiment, the joint between the semiconductor device 1 and the heat radiating part 2 is soldered by reflow soldering.

Specifically, first, the heat radiating part 2 is placed at a predetermined position on the bonding surface of the substrate 10, and then the substrate 10 is carried into a heating furnace. Then, after performing a preheating process at around 180° C., the temperature is raised to around 220° C. to melt the solder. Thereafter, the heat radiating part 2 is soldered to the bonding surface of the substrate 10 by cooling the solder until it solidifies.

The heat radiating part 2 is soldered to the semiconductor device 1 as described above. Other finishing processes are also carried out. In this way, the semiconductor device 1 in which the heat radiating part 2 is integrally provided is completed.

As described above, in the semiconductor device 1 of this embodiment, the joining member 4 forms the porous metal layer 40 in which the pores 41 are uniformly distributed throughout. Therefore, the joint between the semiconductor device 1 and the heat radiating part 2 becomes a spot-like bond. This makes it possible to reduce the temperature distribution over the entire surface of the joint. Further, even if a crack occurs in the joining member 4, it can be absorbed by the pores 41, so that the crack can be restricted from spreading. Furthermore, since the distance between the spotted joints becomes smaller, thermal stress can be reduced. As a result, it is possible to achieve improvement in both of the heat dissipation performance and the durability.

Furthermore, in the semiconductor device 1 of the present embodiment, the porous metal layer 40 has at least one pore 41 within a unit area (i.e., 1 mm²) when viewed in a direction perpendicular to the bonding surface between the semiconductor device 1 and the heat radiating part 2. According to this, as shown in FIG. 2, the durability can be improved.

Further, in the semiconductor device 1 of the present embodiment, the porous metal layer 40 is configured such that the thickness dimension Wp and the void ratio Rv satisfy the relationship of Rv≤−6.23Wp+1. According to this, as shown in FIG. 4, the heat dissipation performance can be improved.

Furthermore, in the semiconductor device 1 of this embodiment, the groove portion 23 is formed in the bonding surface of the heat radiating part 2 with the joining member 4. According to this, in the bonding step, the gas inside the joining member 4 can easily escape to the outside through the groove portion 23, so that the pores 41 can be uniformly distributed within the joining member 4.

A sheet-shaped sheet solder in which flux material is not included is used as the joining member, when a component that requires heat dissipation (for example, an electronic component) and a heat dissipation part are bonded together, and the joint area of the bonded part is large, such as 100 mm² or more. In this case, since soldering is performed by heating in a reducing atmosphere, almost no voids are generated in the joining member. However, when thermal stress is applied to the joining member, it becomes difficult to absorb the stress, and cracks are likely to occur in the joining member.

In contrast, the method for manufacturing the semiconductor device 1 of the present embodiment involves the printing step to apply the paste solder containing a flux material to at least one of the bonding surface of the semiconductor device 1 and the bonding surface of the heat radiating part 2 through a screen mesh. According to this, the pores 41 can be uniformly distributed within the joining member 4. As a result, even if a crack occurs in the joining member 4, it can be absorbed by the pores 41, thereby improving the durability.

The present disclosure is not limited to the embodiment, and can be variously modified as follows within the scope that does not deviate from the gist of the present disclosure.

(1) In the embodiment, air is employed as the ambient fluid and the heat radiating part 2 is configured to radiate heat generated by the semiconductor device 1 to the air, but not limited to this. For example, a refrigerant liquid may be used as the ambient fluid, and the heat radiating part 2 may be immersed in the refrigerant liquid to radiate the heat generated by the semiconductor device 1 to the refrigerant liquid. In this case, an insulating fluid may be used as the refrigerant liquid. Specifically, a fluorine-based inert liquid may be used as the refrigerant liquid. The fluorine-based inert liquid is a refrigerant liquid having excellent insulating properties, heat transfer characteristics, and stability.

(2) In the embodiment, the two linear groove portions 23 are formed in a crisscross pattern on the bonding surface of the plate portion 21 of the heat radiating part 2, but not limited. For example, one, three or more than three groove portions 23 may be formed. Furthermore, the groove portion 23 may be formed at another position on the surface of the heat radiating part 2 to be bonded to the semiconductor device 1, while the end thereof is open to the outside of the heat radiating part 2.

Although the present disclosure has been described in accordance with the examples, it is understood that the present disclosure is not limited to such examples or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

What is claimed is:

1. An electronic component with heat dissipating part comprising:
an electronic part to generate heat during operation;
a heat radiating part configured to radiate heat generated by the electronic part to an ambient fluid; and
a joining member to join the electronic part and the heat radiating part, wherein
a joint area between the electronic part and the heat radiating part is 100 mm² or more,
the joining member forms a porous metal layer in which pores are uniformly distributed, and
the joining member is solder.

2. The electronic component with heat dissipating part according to claim 1, wherein
the porous metal layer has at least one pore formed within a unit area when viewed in a direction perpendicular to a bonding surface between the electronic part and the heat radiating part,
the unit area is 1 mm²,
a length of the porous metal layer in an arrangement direction of the electronic part and the heat radiating part is defined as a thickness dimension Wp,
a ratio of an area of the pores included in the unit area when the porous metal layer is viewed in the direction perpendicular to the bonding surface is defined as a void ratio Rv, and
the thickness dimension and the void ratio satisfy a relationship of Rv≤−6.23Wp+1.

3. The electronic component with heat dissipating part according to claim 1, wherein at least one of a bonding surface of the electronic part with the joining member and a bonding surface of the heat radiating part with the joining member is plated with nickel.

4. The electronic component with heat dissipating part according to claim 1, wherein a groove portion is formed in a bonding surface of the heat radiating part with the joining member.
